(19) United States
(12) Patent Application Publication
(10) Pub. No.: US 2015/0240354 A1
(43) Pub. Date: Aug. 27, 2015

(54) ABRASION RESISTANT, HYDROPHOBIC AND OLEOPHOBIC COATED FILM AND METHOD OF PRODUCTION THEREOF

(71) Applicant: RESEARCH & BUSINESS FOUNDATION SUNGKYUNKWAN UNIVERSITY, Suwon-si (KR)

(72) Inventors: Jeongeon HAN, Seoul (KR); Yoonseok CHOI, Suwon-si (KR); Jun Suck LEE, Wonju-si (KR)

(73) Assignee: RESEARCH & BUSINESS FOUNDATION SUNGKYUNKWAN UNIVERSITY, Suwon-si (KR)

(21) Appl. No.: 14/505,871

(22) Filed: Oct. 3, 2014

(30) Foreign Application Priority Data
Feb. 25, 2014 (KR) 10-2014-0022201

(51) Int. Cl. C23C 16/40; C23C 16/505; C23C 16/50

(52) U.S. Cl. CPC C23C 16/401; C23C 16/50; C23C 16/505

(57) ABSTRACT

A method of preparing a coated film, and an abrasion resist, hydrophobic and oleophobic coated film are provided. The method involves forming a SiOₓ thin film, forming a first hydrophobic thin film on the SiOₓ thin film, and forming a second oleophobic thin film on the first hydrophobic thin film.

### CROSS-REFERENCE TO RELATED APPLICATION

This application claims the benefit under 35 USC 119(a) of Korean Patent Application No. 10-2014-0022201 filed on Feb. 25, 2014, in the Korean Intellectual Property Office, the entire disclosures of which is incorporated herein by reference for all purposes.

### BACKGROUND

1. Field

The following description relates to a preparing method for an abrasion resistant, hydrophobic and oleophobic coated film, and an abrasion resistant, hydrophobic and oleophobic coated film prepared by the method.

2. Description of Related Art

Hydrophobic coating has great industrial applicability due to its unique characteristics. For instance, hydrophobic coating may exhibit dust resistance, chemical resistance, fouling resistance, static electricity prevention, and water repellency. For that reason, hydrophobic coatings are used in generating antifogging films and in preventing freezing of water on car window surfaces and the like. In recent years, hydrophobic coatings have been used in forming fingerprint resistant films for tough screen devices such as smart phones.

A hydrocarbon-based material or fluorocarbon-based material is often used to form a fingerprint resistant film. The method for forming a fingerprint resistant film on a substrate may be characterized as either a wet method or a dry method. The dry method refers to a plasma enhanced chemical vapor deposition (PECVD) method. Although using the commonly used PECVD method is preferable in the aspect of industrialization of the technology and mass production, a hydrophobic thin film using the PECVD method has not yet been industrialized.

Korean Patent Application Publication No. 2007-0006991 relates to a surface coating method that uses atmospheric pressure plasma for hydrophobic or super-hydrophobic treatment. Specifically, a method for coating a surface of an object with hydrocarbons or fluorocarbons by generating plasma under an atmospheric pressure in order to enable the surface of the object to exhibit hydrophobicity or super-hydrophobicity is disclosed.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, there is provided a method of preparing a coated film, the method involving: forming a SiOₓ thin film by performing plasma enhanced chemical vapor deposition (PECVD) using an organosilane precursor and oxygen; forming a first hydrophobic thin film on the SiOₓ thin film by performing PECVD using an organosilane precursor; and forming a second oleophobic thin film on the first hydrophobic thin film by performing PECVD using a fluorocarbon-based gas precursor.

The SiOₓ thin film may be a super-hydrophobic thin film, and the coated film may be abrasion resistant, hydrophobic and oleophobic.

The general aspect of the method may further involve applying a plasma treatment to the SiOₓ thin film after forming the SiOₓ thin film.

The plasma treatment of the SiOₓ thin film may be carried out with O₂ plasma or Ar plasma.

The organosilane precursor may include SiₓC_{y}H_{z}, in which x is an integer between 1 and 4, y is an integer between 3 and 8, and z is an integer between 10 and 24.

The fluorocarbon-based gas precursor may include CₓE_{y} in which x is an integer between 1 and 3, and y is an integer between 4 and 8.

The first thin film may be formed by performing PECVD using a RF power ranging between 5 MHz and 30 MHz.

The second thin film may be formed by performing PECVD using a MF power ranging between 10 kHz and 300 kHz.

In another general aspect, there is provided a coated film prepared by the above-described method, wherein the coated film exhibits abrasion resistance, hydrophobicity and oleophobicity.

A water contact angle of the coated film may be 110° or more, a oil contact angle may be 80° or more, and a pencil hardness may be 7H or more.

The coating may include a SiOₓ thin film, a first hydrophobic thin film, and a second oleophobic thin film formed in that order.

In another general aspect, there is provided a coated film comprising a SiOₓ thin film, a first hydrophobic thin film, and a second oleophobic thin film formed in that order, wherein the coated film exhibits a water contact angle is 110° or more, an oil contact angle is 80° or more, and a pencil hardness is 7H or more.

The SiOₓ thin film is a super-hydrophobic thin film obtained by plasma enhanced chemical vapor deposition (PECVD) using an organosilane precursor and oxygen, and the second oleophobic thin film is an oleophobic thin film obtained by PECVD using a fluorocarbon-based gas precursor.

Other features and aspects will be apparent from the following detailed description, the drawings, and the claims.

### BRIEF DESCRIPTION OF THE DRAWINGS

FIG. 1 is a flowchart illustrating an example of a method of preparing an abrasion resistant, hydrophobic and oleophobic coated film.

FIG. 2 is a schematic view of a PECVD that is used in an example of a method of preparing an abrasion resistant, hydrophobic and oleophobic coated film.

FIG. 3 is a schematic view of an abrasion resistant, hydrophobic and oleophobic coated film in accordance with an example embodiment.

FIG. 4A is a graph that illustrates a change in water contact angle based on a change in substrate temperature in accordance with an example of a method of preparing a coated film.

FIG. 4B is a graph illustrating a change in oil contact angle based on a change in substrate temperature in accordance with an example of a method of preparing a coated film.

FIG. 5 is a graph illustrating a change in pencil hardness based on a change in substrate temperature in accordance with an example of a method of preparing a coated film.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the systems, apparatuses and/or methods described herein will be apparent to one of ordinary skill in the art. The progression of processing steps and/or operations described is an example; however, the sequence of and/or operations is not limited to that set forth herein and may be changed as is known in the art, with the exception of steps and/or operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Throughout the present disclosure, the terms “connected to” or “coupled to” are used to designate a connection or coupling of one element to another element and include both a case where an element is “directly connected or coupled to” another element and a case where an element is “electronically connected or coupled to” another element via still another element.

Throughout the present disclosure, the term “on” that is used to designate a position of one element with respect to another element includes both a case that the one element is adjacent to the another element and a case that any other element exists between these two elements.

Throughout the whole document of the present disclosure, the term “comprises or includes” and/or “comprising or including” used in the document means that one or more other components, steps, operations, and/or the existence or addition of elements are not excluded in addition to the described components, steps, operations and/or elements. Throughout the whole document of the present disclosure, the terms “about or approximately” or “substantially” are intended to have meanings close to numerical values or ranges specified with an allowable error and intended to prevent accurate or absolute numerical values disclosed for understanding of the present invention from being illegally or unfairly used by any unconscionable third party. Throughout the whole document, the term “step of” does not mean “step for.”

Throughout the present disclosure, the term “combination(s) of” included in Markush type description means mixture or combination of one or more components, steps, operations and/or elements selected from a group consisting of components, steps, operation and/or elements described in Markush type and thereby means that the disclosure includes one or more components, steps, operations and/or elements selected from the Markush group.

Throughout the present disclosure, the description “A and/or B” means “A or B, or A and B.”

A “super-hydrophobic” surface refers to a highly hydrophobic surface that is difficult to wet. The super-hydrophobicity of a surface may be assessed based on the contact angle of a water droplet on the surface. For example, the contact angle of a super-hydrophobic surface may be 110° or greater.

Throughout the whole document of the present disclosure, a “SiOₓ thin film” means a silica-based thin film, and x may be a value around 2, preferably, x is 2. When x is 2, a high quality thin film can be obtained, but may not be limited thereto. If the SiOₓ thin film has been formed on a substrate, adhesion to a hydrophobic thin film can be improved by carrying out O₂ plasma or Ar plasma treatment for the SiOₓ thin film. If the SiOₓ thin film has not been formed on a substrate, a hydrophobic thin film may not be easily formed, or the adhesion may become weak, thereby, deteriorating the endurance of the thin film.

As noted above, a hydrophobic film may be formed by coating a surface of an object with hydrocarbons or fluorocarbons, using plasma generated under an atmospheric pressure.

However, in the event that a hydrophobic thin film is formed by surface-coating a hydrocarbon-based material, the hydrocarbon thin film tends to have oleophilicity with respect to oil, due to its chemical characteristics. Oil also has a chemical formula by connection of hydrocarbons. Due to the chemical characteristics of the thin film and oil, the hydrophobic thin film is likely to become oleophilic. In addition, the hydrophobic thin film is easily abraded by external shocks. Accordingly, in order to form an abrasion resistant, oleophobic thin film, it may be preferable to form a fluorocarbon film, rather than a hydrocarbon thin film.

Hereinafter, various examples of the present disclosure will be described in detail with reference to the accompanying drawings. However, the present disclosure may not be limited to the example embodiments and the drawings.

In a first aspect of the present disclosure, there is provided a preparing method for a coated film having abrasion resistance, hydrophobicity and oleophobicity, which includes: forming a SiOₓ thin film on a substrate by plasma enhanced chemical vapor deposition (PECVD) using an organosilane precursor and oxygen; forming a first hydrophobic thin film on the SiOₓ thin film by PECVD using an organosilane precursor; and forming a second oleophobic thin film on the first hydrophobic thin film by PECVD using a flurorocarbon-based gas precursor.

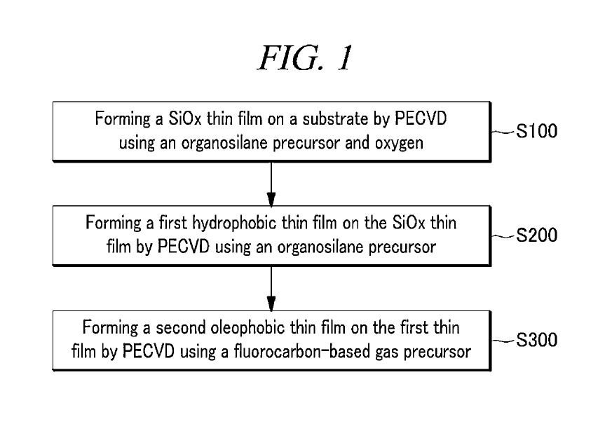

A coated film having the abrasion resistance, hydrophobicity and oleophobicity in accordance with the present disclosure, may be formed by the method as illustrated in the flowchart of FIG. 1. The method of forming the coated film involves forming a thin film on a substrate by PECVD, using an organosilane precursor and oxygen (S100). Any common hard or flexible substrate may be used without limitation as the substrate. For example, in the event that a polymer-based substrate is used as the substrate, a SiOₓ thin film may be formed in S100. Then, a hydrophobic, oleophobic thin film may be formed for improvement of surface roughness. The organosilane precursor for forming the SiOₓ thin film may include a member selected from the group consisting of tetraethylorthosilicate (TEOS), hexamethyldisiloxane (HMDSO), octamethylcyclotetrasiloxane (OMCTS), and combinations thereof; however, the organosilane precursor is not be limited thereto.

In accordance with an example of the present disclosure, plasma treatment may be additionally carried out after the formation of the SiOₓ thin film; however, the method is not limited thereto. For example, plasma treatment for the SiOₓ thin film may be carried out with 02 plasma or Ar plasma; however, the method is not limited thereto. For example, if O₂ plasma treatment is carried out as the surface treatment of the substrate, an OH-(hydroxyl group) is formed on the substrate surface so that the surface of the substrate is modified to be hydrophilic, and the surface of the substrate modified to be hydrophilic may form a compact thin film having improved adhesion without defects, when the subsequent first thin film is deposited. However, the method is not limited thereto. For example, in the event that Ar plasma treatment is carried out as the surface treatment of the substrate, a surface area of the substrate may be physically enlarged, and thereby, improving adhesion; however, the method is not limited thereto. After the plasma treatment is performed in accordance with the present disclosure, the surface of the SiOₓ thin film is changed to be super-hydrophilic, and a hydrophobic thin film rich in a CH₃ group may be formed on the super-hydrophilic SiOₓ thin film by using an organosilane precursor.

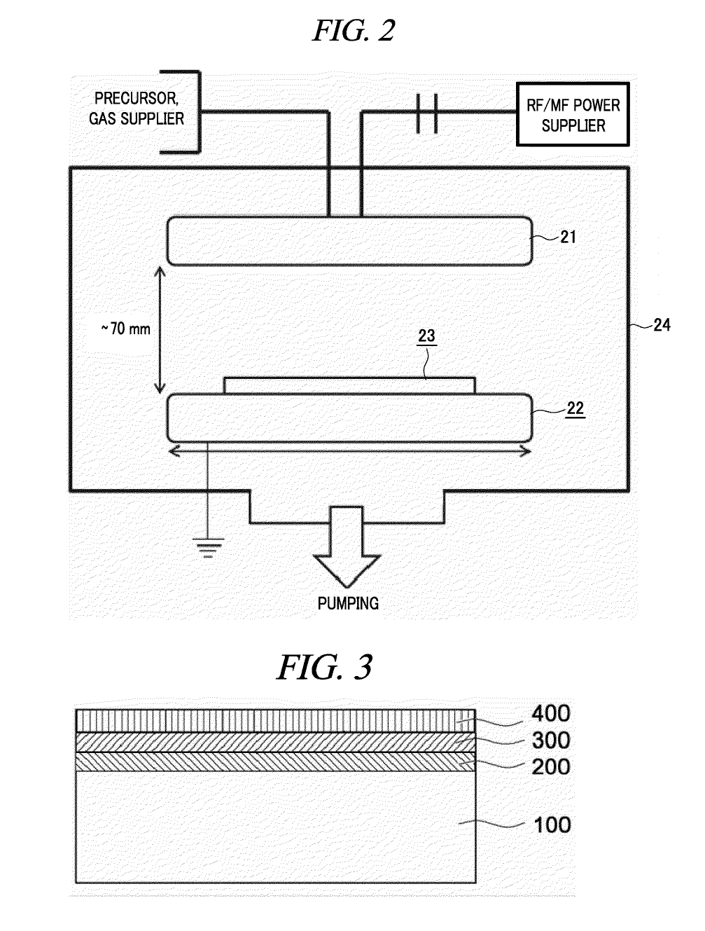

The SiOₓ thin film, the first hydrophobic thin film, and the second oleophobic thin film are formed by performing plasma enhanced chemical vapor deposition (PECVD), respectively. An example of a PECVD that may be used includes a capacitively coupled plasma (CCP) type PECVD; however, the type of the PECVD is not limited thereto. As illustrated in FIG. 2, the CCP type PECVD includes PECVD using two (2) electrodes 21, 22, whereby power is applied to an upper electrode 21, and a precursor is introduced into a chamber 24 through a shower head provided in the upper electrode 21, and wherein a lower electrode 22 may include the grounded or floated state such that the lower electrode 22 may serve as a substrate holder to locate a substrate 23 on the lower electrode 22. In addition, a device for raising a substrate temperature may be added to the lower electrode 22. In case of the CCP type PECVD, plasma is generated by a capacitive electric field formed by charges distributed on the surfaces of the upper and lower electrodes 21, 22. If the coated film is prepared by using the PECVD in accordance with the present disclosure, a transparent, abrasion resistant, hydrophobic and oleophobic coated thin film can be prepared; a thickness of the coated film can be adjusted; and the coated film may be a high quality coated film having a compact structure. In this example, a basic pressure of the PECVD may be set to approximately 10 mT or lower, but the method is not limited thereto. For example, the basic pressure may be set to approximately 10 mT or lower, approximately 8 mT or lower, approximately 5 mT or lower, or approximately 3 mT or lower; however, the basic pressure is not limited thereto. In addition, a process pressure of the PECVD may be set to a value in a range of from approximately 100 mT to approximately 200 mT; however the method is not limited thereto. For example, the process pressure of the PECVD may be set to a value in a range of from approximately 100 mT to approximately 200 mT, from approximately 110 mT to approximately 200 mT, from approximately 120 mT to approximately 200 mT, from approximately 130 mT to approximately 200 mT, from approximately 140 mT to approximately 200 mT, from approximately 150 mT to approximately 200 mT, from approximately 160 mT to approximately 200 mT, from approximately 170 mT to approximately 200 mT, from approximately 180 mT to approximately 200 mT, from approximately 190 mT to approximately 200 mT, from approximately 100 mT to approximately 190 mT, from approximately 100 mT to approximately 180 mT, from approximately 100 mT to approximately 170 mT, from approximately 100 mT to approximately 160 mT, from approximately 100 mT to approximately 150 mT, from approximately 100 mT to approximately 140 mT, from approximately 100 mT to approximately 130 mT, from approximately 100 mT to approximately 120 mT, or from approximately 100 mT to approximately 110 mT, but may not be limited thereto. Furthermore, a process temperature of the PECVD may be set to a value ranging from a room temperature to approximately 150° C.; however the method is not limited thereto. For example, the process temperature may range from a room temperature to approximately 150° C., from approximately 50° C. to approximately 150° C., from approximately 60° C. to approximately 150° C., from approximately 70° C. to approximately 150° C., from approximately 80° C. to approximately 150° C., from approximately 90° C. to approximately 150° C., from approximately 100° C. to approximately 150° C., from approximately 110° C. to approximately 150° C., from approximately 120° C. to approximately 150° C., from approximately 130° C. to approximately 150° C., from approximately 140° C. to approximately 150° C., from a room temperature to approximately 140° C., from a room temperature to approximately 130° C., from a room temperature to approximately 120° C., from a room temperature to approximately 110° C., from a room temperature to approximately 100° C., from a room temperature to approximately 90° C., from a room temperature to approximately 80° C., from a room temperature to approximately 70° C., from a room temperature to approximately 60° C., or from a room temperature to approximately 50° C., but may not be limited thereto. For example, when a substrate temperature of the first and/or second thin film increases, mechanical strength can be improved. In addition, when the substrate temperature increases to from approximately 100° C. to approximately 150° C. upon the deposition of the second thin film, oleophobicity and abrasion resistance are improved.

Subsequently, a first hydrocarbon-based hydrophobic thin film is formed on the SiOₓ thin film by PECVD using an organosilane precursor (S200).

In accordance with an example embodiment of the present disclosure, the organosilane precursor may include SiₓC_{y}H_{z} wherein x is an integer between 1 and 4, y is an integer between 3 and 8, and z is an integer between 10 and 24; however, the precursor is not limited thereto. For example, the organosilane precursor may include a member selected from the group consisting of hexamethyldisilane (HMDS), trimethylsilane (TMS), tetraethylorthosilicate (TEOS), hexamethyldisiloxane (HMDSO), octamethylcyclotetrasiloxane (OMCTS), and combinations thereof, but may not be limited thereto.

In accordance with an example embodiment of the present disclosure, the first hydrophobic thin film may be formed by PECVD using radio frequency (RE) power of from approximately 5 MHz to approximately 30 MHz, but may not be limited thereto. For example, the first hydrophobic thin film may be formed by PECVD using RF power of from approximately 5 MHz to approximately 30 MHz, from approximately 7 MHz to approximately 30 MHz, from approximately 10 MHz to approximately 30 MHz, from approximately 13.56 MHz to approximately 30 MHz, from approximately 15 MHz to approximately 30 MHz, from approximately 17 MHz to approximately 30 MHz, from approximately 20 MHz to approximately 30 MHz, from approximately 23 MHz to approximately 30 MHz, from approximately 25 MHz to approximately 30 MHz, from approximately 27 MHz to approximately 30 MHz, from approximately 5 MHz to approximately 27 MHz, from approximately 5 MHz to approximately 25 MHz, from approximately 5 MHz to approximately 23 MHz, from approximately 5 MHz to approximately 20 MHz, from approximately 5 MHz to approximately 17 MHz, from approximately 5 MHz to approximately 15 MHz, from approximately 5 MHz to approximately 13.56 MHz, from approximately 5 MHz to approximately 10 MHz, from approximately 5 MHz to approximately 7 MHz, from approximately 7 MHz to approximately 13.56 MHz, from approximately 10 MHz to approximately 13.56 MHz, from approximately 13.56 MHz to approximately 15 MHz, from approximately 13.56 MHz to approximately 17 MHz, from approximately 13.56 MHz to approximately 20 MHz, from approximately 13.56 MHz to approximately 23 MHz, from approximately 13.56 MHz to approximately 25 MHz, or from approximately 13.56 MHz to approximately 27 MHz, but may not be limited thereto.

The first hydrophobic thin film in accordance with the present disclosure may be formed on the substrate with a thickness of from approximately 10 nm to approximately 100 nm; however, the thickness is not limited thereto. For example, the hydrophobic first thin film may be formed with a thickness of from approximately 10 nm to approximately 100 nm, from approximately 20 nm to approximately 100 nm, from approximately 30 nm to approximately 100 nm, from approximately 40 nm to approximately 100 nm, from approximately 50 nm to approximately 100 nm, from approximately 60 nm to approximately 100 nm, from approximately 70 nm to approximately 100 nm, from approximately 80 nm to approximately 100 nm, from approximately 90 nm to approximately 100 nm, from approximately 10 nm to approximately 90 nm, from approximately 20 nm to approximately 90 nm, from approximately 30 nm to approximately 90 nm, from approximately 40 nm to approximately 90 nm, from approximately 50 nm to approximately 90 nm, from approximately 60 nm to approximately 90 nm, from approximately 70 nm to approximately 90 nm, from approximately 80 nm to approximately 90 nm, from approximately 10 nm to approximately 80 nm, from approximately 20 nm to approximately 80 nm, from approximately 30 nm to approximately 80 nm, from approximately 40 nm to approximately 80 nm, from approximately 50 nm to approximately 80 nm, from approximately 60 nm to approximately 80 nm, from approximately 70 nm to approximately 80 nm, from approximately 10 nm to approximately 70 nm, from approximately 20 nm to approximately 70 nm, from approximately 30 nm to approximately 70 nm, from approximately 40 nm to approximately 70 nm, from approximately 50 nm to approximately 70 nm, from approximately 60 nm to approximately 70 nm, from approximately 10 nm to approximately 60 nm, from approximately 20 nm to approximately 60 nm, from approximately 30 nm to approximately 60 nm, from approximately 40 nm to approximately 60 nm, from approximately 50 nm to approximately 60 nm, from approximately 10 nm to approximately 50 nm, from approximately 20 nm to approximately 50 nm, from approximately 30 nm to approximately 50 nm, from approximately 40 nm to approximately 50 nm, from approximately 10 nm to approximately 40 nm, from approximately 20 nm to approximately 40 nm, from approximately 30 nm to approximately 40 nm, from approximately 10 nm to approximately 30 nm, from approximately 20 nm to approximately 30 nm, or from approximately 10 nm to approximately 20 nm, but may not be limited thereto. For example, if the first hydrophobic thin film has a thickness of approximately 100 nm, hydrophobicity of a water contact angle of approximately 10° C. or larger can be obtained. By forming the first hydrophobic thin film in accordance with the present disclosure, the subsequent second oleophobic thin film is formed on the first thin film while having a strong adhesion, and the abrasion resistance of the coated film in accordance with the present disclosure can be improved.

Subsequently, a second fluorocarbon-based oleophobic thin film is formed on the first hydrophobic thin film by using a fluorocarbon-based gas precursor, as in S300 of FIG. 1.

In accordance with an example embodiment of the present disclosure, the fluorocarbon-based gas precursor may include CₓF_{y} wherein x is an integer between 1 and 3, and y is an integer between 4 and 8; however, but the precursor is not limited thereto. According to one example, the fluorocarbon-based gas precursor may include a member selected from the group consisting of CF₄, C₂F₆, C₃F₈, and combinations thereof.

In accordance with an example embodiment of the present disclosure, the second oleophobic thin film may be formed by PECVD, to which a middle frequency (MF) power of from approximately 10 kHz to approximately 300 kHz has been applied; however, the method is not limited thereto. In this example, the MF power may be set to a value in a range of from approximately 10 kHz to approximately 300 kHz, from approximately 50 kHz to approximately 300 kHz, from approximately 100 kHz to approximately 300 kHz, from approximately 150 kHz to approximately 300 kHz, from approximately 200 kHz to approximately 300 kHz, from approximately 250 kHz to approximately 300 kHz, from approximately 10 kHz to approximately 250 kHz, from approximately 50 kHz to approximately 250 kHz, from approximately 100 kHz to approximately 250 kHz, from approximately 150 kHz to approximately 250 kHz, from approximately 200 kHz to approximately 250 kHz, from approximately 10 kHz to approximately 200 kHz, from approximately 50 kHz to approximately 200 kHz, from approximately 100 kHz to approximately 200 kHz, from approximately 150 kHz to approximately 200 kHz, from approximately 10 kHz to approximately 150 kHz, from approximately 50 kHz to approximately 150 kHz, from approximately 100 kHz to approximately 150 kHz, from approximately 10 kHz to approximately 100 kHz, from approximately 50 kHz to approximately 100 kHz, or from approximately 10 kHz to approximately 50 kHz, but may not be limited thereto. When forming the second oleophobic thin film, the MF power in accordance with the present disclosure, instead of the RF power used for the first thin film, is used because when fluorine may be formed, when forming the thin film, due to the high dissociation phenomenon of the fluorocarbon-based gas. The fluorine is easily diffused within the thin film, and the diffused fluorine causes the problem of adhesion and endurance of the thin film. However, when the second oleophobic thin film is formed by the PECVD using the MF power, the dissociation of the fluorocarbon-based gas precursor does not exceedingly occur, and since the fluorocarbon-based gas precursor has large kinetic energy, the deposition of the thin film is facilitated. As a result of the activation effect by the large kinetic energy, the thin film having high density can be effectively formed. Further, since dissociated fluorine is small, it does not affect the adhesion and/or endurance of the thin film.

The second oleophobic thin film, which is formed by the fluorocarbon-based gas precursor through the PECVD, may be formed on the first thin film while having a thickness of from approximately 10 nm to approximately 20 nm; however, the method is not limited thereto. For example, the thickness of the second oleophobic thin film may range from approximately 10 nm to approximately 20 nm, from approximately 12 nm to approximately 20 nm, from approximately 14 nm to approximately 20 nm, from approximately 16 nm to approximately 20 nm, from approximately 18 nm to approximately 20 nm, from approximately 19 nm to approximately 20 nm, from approximately 10 nm to approximately 19 nm, from approximately 12 nm to approximately 19 nm, from approximately 14 nm to approximately 19 nm, from approximately 16 nm to approximately 19 nm, from approximately 18 nm to approximately 19 nm, from approximately 10 nm to approximately 18 nm, from approximately 12 nm to approximately 18 nm, from approximately 14 nm to approximately 18 nm, from approximately 16 nm to approximately 18 nm, from approximately 10 nm to approximately 16 nm, from approximately 12 nm to approximately 16 nm, from approximately 14 nm to approximately 16 nm, from approximately 10 nm to approximately 14 nm, from approximately 12 nm to approximately 14 nm, or from approximately 10 nm to approximately 12 nm; however, the thickness is not limited thereto. For example, if the second oleophobic thin film has the above-described range of the thickness, oleophobicity of an oil contact angle of approximately 80° or larger may be obtained.

In a second aspect of the present disclosure, there is provided a coated film prepared by the method according to the first aspect of the present disclosure, the coated film exhibiting abrasion resistance, hydrophobicity, and oleophobicity.

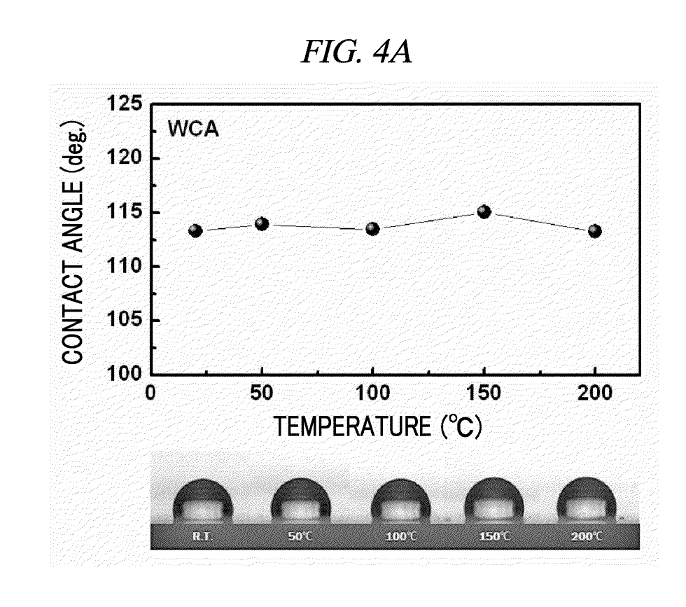

As illustrated in FIG. 3, the coated film may include a SiOₓ thin film 200 formed on a substrate 100, a first hydrophobic thin film 300 and a second oleophobic thin film 400 formed on a the first hydrophobic thin film 300, but may not be limited thereto. The coated film prepared by forming the hydrophobic and oleophobic thin films on the SiOₓ thin film 200 can exhibit superior characteristics in abrasion resistance, corrosion resistance, fingerprint resistance, endurance and so on.

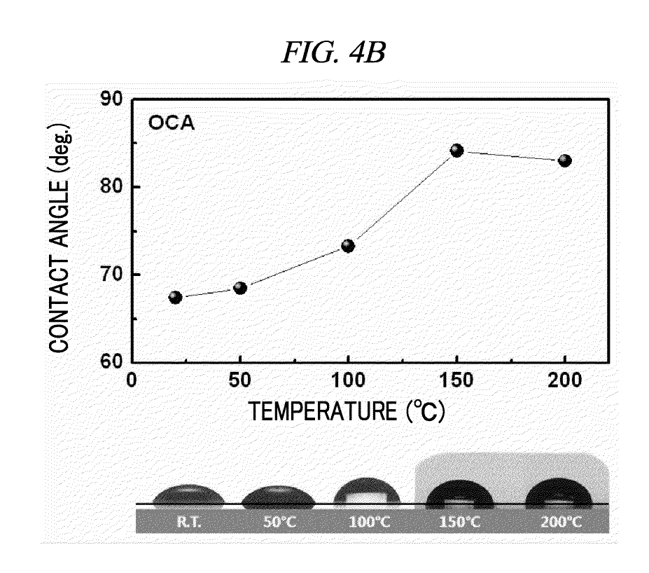

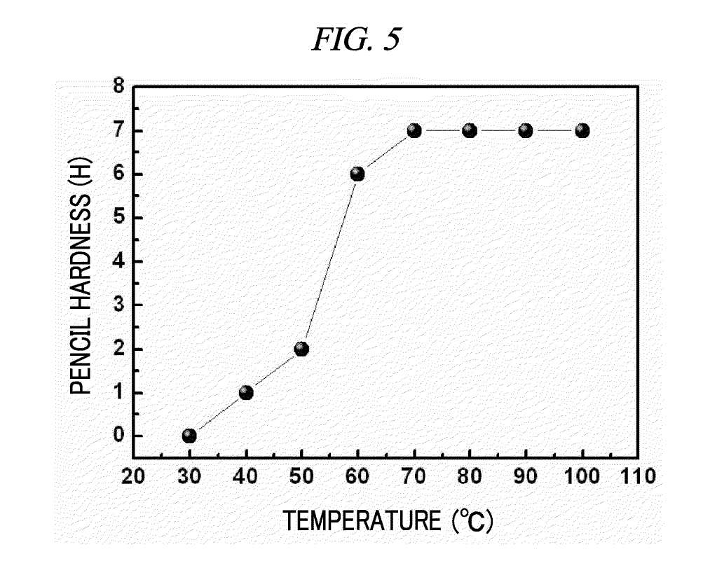

In accordance with an example embodiment of the present disclosure, as illustrated in FIG. 4A, a water contact angle (WCA), which was measured by dropping approximately 4 μL water on the surface of the coated film, is 110° or larger. For example, the water contact angle may be greater than 112° or larger. As illustrated in FIG. 4B, an oil contact angle (OCA), which was measured by dropping approximately 4 μL diiodomethane (CH₂I₂) on the surface of the coated film, is 80° or larger. In one example, the oil contact angle may be greater than 80° and the temperature may be greater than 120°, 130°, or 150°. In addition, as illustrated in FIG. 5, pencil hardness is 7H or more. In one example, the pencil hardness is 6.5H or more or 7H or more, and the temperature may be 60° or more, 70° or more, or 80° or more. However, the characteristics of the coated film are not limited thereto, and different characteristics may be obtained in another example.

As described above, the present disclosure provides an example of a method of preparing an abrasion resistant, hydrophobic and oleophobic coated film, and an abrasion resistant, hydrophobic and oleophobic coated film formed by the method.

According to one example, there is provided a method of preparing a coated film having abrasion resistance, hydrophobicity and oleophobicity, which includes: forming a SiOₓ thin film on a substrate by plasma enhanced chemical vapor deposition (PECVD) using an organosilane precursor and oxygen; forming a first hydrophobic thin film on the SiOₓ thin film by PECVD using an organosilane precursor; and forming a second oleophobic thin film on the first hydrophobic thin film by PECVD using a flurorocarbon-based gas precursor.

According to a second example, there is provided a coated film prepared by the method according to the first aspect of the present disclosure, and having abrasion resistance, hydrophobicity, and oleophobicity.

As a result of the coating with the hydrophobic thin film, when the hydrophobic thin film is applied to windows, ventilators or others, the windows, ventilators or others, the surface can be kept clean because dusts do not cling thereto, due to the antistatic characteristic of the hydrophobic thin film. When the hydrophobic thin film is applied to car windows or others, fogging is prevented, and freezing does not occur since water is repelled, so that froze and burst in winter can be effectively prevented. Furthermore, because water is blocked from the surface, the hydrophobic thin film is also useful for corrosion resistance coating. Due to the corrosion resistant characteristic, the hydrophobic thin film may be used for corrosion resistant materials for implants and prosthetic appliances, stents for blood vessel medical procedures, and the like, and the adsorption of thrombus or the like can be prevented through the abrasion resistant, hydrophobic, oleophobic coating. Further, chemical and physical reliability is improved through the abrasion resistant and oleophobic coating. Thus, the abrasion resistance and oleophobicity are beneficial for commercialization of products coated with the thin film.

In accordance with the present disclosure, since the coating with the oleophobic thin film is carried out by PECVD having middle frequency (ME) power, there is little possibility of formation of hydrofluoric acid during a process, and a thin film having high reliability can be prepared. Especially, in case of high oleophobicity, since the fingerprint resistance effect is excellent, and a frictional force is significantly reduced upon contact with a surface, thereby, increasing a slipping effect, the thin film is useful for touch screens. Furthermore, the coating with the oleophobic thin film is useful for electronic devices such as smart phones, due to its characteristic that cosmetics or the like are not easily stained thereon and are easily removed. By applying the MF power, division of a precursor becomes weak, and strong ions and radicals are contacted on a coated surface while having strong kinetic energy, so as to contribute to deposition of a thin film by kinetic energy activation. As a result, the density of the thin film increases, and the oleophobicity and abrasion resistance of the thin film are improved. Further, the formation of fluorine atoms is significantly reduced, so that the concern of performance deterioration resulting from chemical etching is reduced.

Since the coated film having both hydrophobicity and oleophobicity in accordance with the present disclosure does not cause deterioration of endurance of the thin film resulting from fluorine, and is prepared through a relatively simple process, industrialization is facilitated. In addition, since the thin film can be prepared simply by changing precursor or process conditions for equipment used in a conventional PECVD process, actual possibility of industrialization is significantly high. By using the PECVD process, a compact thin film of which thickness is adjustable can be prepared, a multilayer thin film can also be easily prepared, the preparation costs are low, compared to other processes, and process time can be reduced to not exceed 10 minutes.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

### EXPLANATION OF CODES

100: Substrate
200: SiOₓ thin film
300: First thin film
400: Second thin film

We claim:

1. A method of preparing a coated film, the method comprising:
forming a SiOₓ thin film by performing plasma enhanced chemical vapor deposition (PECVD) using an organosilane precursor and oxygen;
forming a first hydrophobic thin film on the SiOₓ thin film by performing PECVD using an organosilane precursor; and
forming a second oleophobic thin film on the first hydrophobic thin film by performing PECVD using a fluorocarbon-based gas precursor.

2. The method of claim 1, wherein the SiOₓ thin film is a super-hydrophobic thin film, and the coated film is abrasion resistant, hydrophobic and oleophobic.

3. The method of claim 1, further comprising:
applying a plasma treatment to the SiOₓ thin film after forming the SiOₓ thin film.

4. The method of claim 3,
wherein the plasma treatment of the SiOₓ thin film is carried out with O₂ plasma or Ar plasma.

5. The method of claim 1,
wherein the organosilane precursor comprises SiₓC_{y}H_{z}, in which x is an integer between 1 and 4, y is an integer between 3 and 8, and z is an integer between 10 and 24.

6. The method of claim 1,
wherein the fluorocarbon-based gas precursor comprises CₓF_{y} in which x is an integer between 1 and 3, and y is an integer between 4 and 8.

7. The method of claim 1,
wherein the first thin film is formed by performing PECVD using a RF power ranging between 5 MHz and 30 MHz.

8. The method of claim 1,
wherein the second thin film is formed by performing PECVD using a MF power ranging between 10 kHz and 300 kHz.

9. A coated film prepared by the method of claim 1, wherein the coated film exhibits abrasion resistance, hydrophobicity and oleophobicity.

10. The coated film of claim 9,
wherein a water contact angle is 110° or more, an oil contact angle is 80° or more, and a pencil hardness is 7H or more.

11. The coated film of claim 9, the coating comprising a SiOₓ thin film, a first hydrophobic thin film, and a second oleophobic thin film formed in that order.

12. A coated film comprising a SiOₓ thin film, a first hydrophobic thin film, and a second oleophobic thin film formed in that order, wherein the coated film exhibits a water contact angle is 110° or more, an oil contact angle is 80° or more, and a pencil hardness is 7H or more.

13. The coated film of claim 12, wherein the SiOₓ thin film is a super-hydrophobic thin film obtained by plasma enhanced chemical vapor deposition (PECVD) using an organosilane precursor and oxygen, and the second oleophobic thin film is an oleophobic thin film obtained by PECVD using a fluorocarbon-based gas precursor.
